(19) United States
(12) Patent Application Publication
(10) Pub. No.: US 2007/0207592 A1
(43) Pub. Date: Sep. 6, 2007

(54) Wafer bonding of damascene-patterned metal/adhesive redistribution layers

(76) Inventors: James Jian-Qiang Lu, Troy, NY (US); J. Jay McMahon, Clifton Park, NY (US); Ronald J. Gutmann, Troy, NY (US)

Correspondence Address: FISH & RICHARDSON PC, P.O. BOX 1022, MINNEAPOLIS, MN, 55440-1022, US

(21) Appl. No.: 11/368,316

(22) Filed: Mar. 3, 2006

(51) Int. Cl. H01L 21/30

(52) U.S. Cl. 438/455

(57) ABSTRACT

Wafer bonding of patterned metal/adhesive layers, and related components, processes, systems and methods are disclosed.

### FEDERALLY SPONSORED RESEARCH OR DEVELOPMENT

The U.S. Government may have certain rights in this invention pursuant to Grant No. C020104 awarded by NYSTAR and Grant No. B-12-M06-S4 awarded by MARCO.

### BACKGROUND

Three-dimensional (3D) integration technology can be used to reduce interconnect delays by reducing the length and the number of interconnect lines on a chip of electronic integrated circuits (ICs) and to realize heterogeneous integration of technologies and systems. In general, 3D integration requires wafer-to-wafer alignment, wafer bonding, wafer thinning, and formation of inter-wafer interconnections.

### SUMMARY

According to an aspect of the present invention, a method includes forming a patterned bonding layer on a first substrate and forming a patterned bonding layer on a second substrate. The patterned bonding layer on the first substrate includes a first region and a second region. The first region is comprised of a conductive material and the second region is comprised of a non-conductive adhesive material. The patterned bonding layer on the second substrate includes a first region and a second region. The first region is comprised of a conductive material and the second region is comprised of a non-conductive adhesive material. The method also includes urging the first substrate and the second substrate together to bond at least a portion of the first region of the patterned bonding layer of the first substrate and at least a portion of the first region of the patterned bonding layer of the second substrate and to bond at least a portion of the second region of the patterned bonding layer of the first substrate and at least a portion of the second region of the patterned bonding layer of the second substrate.

Embodiments can include one or more of the following.

The non-conductive adhesive material can include a patternable adhesive. The non-conductive adhesive material can include benzocyclobutene (BCB). The conductive material can be a metal. The metal can be copper.

The method can also include chemical or plasma cleaning of at least one of the first substrate and the second substrate prior to bonding the first substrate to the second substrate. Forming the patterned bonding layer on the first substrate can include depositing an adhesive layer onto the first substrate, partially curing the adhesive layer, etching the adhesive layer to form a patterned adhesive layer, and depositing the conductive material onto the patterned adhesive layer. Forming a patterned bonding layer on a first substrate can include removing portions of the conductive material disposed above the adhesive material to form a nearly planar surface.

The non-conductive adhesive material can be a partially cured polymer layer. The polymer layer can have a crosslink percentage between 30% and 50%. Forming the patterned bonding layer on the second substrate can include depositing a adhesive layer onto the second substrate, partially curing the adhesive layer if needed and applicable, etching the adhesive layer to form a patterned adhesive layer, and depositing the conductive material onto the patterned adhesive layer. The adhesive layer can be a partially cured polymer layer. Forming a patterned bonding layer on a second substrate can include removing portions of the conductive material situated above the adhesive material to form a nearly planar surface. Partially curing the polymer layer can include curing the polymer layer such that the polymer layer has a crosslink percentage between 30% and 50%.

Attaching the first substrate to the second substrate can include applying a uniform pressure to the substrates, the pressure being at least about 40 PSI and heating the first substrate and the second substrate to a temperature from about 250 degrees to about 400 degrees. The method can also include removing a portion of the first substrate subsequent to bonding the first substrate to the second substrate. Removing a portion of the first substrate can include mechanically grinding the first substrate to remove a first portion of the first substrate, performing a chemical mechanical polishing (CMP) process to remove damage caused by grinding process, and chemically etching the first substrate to remove a second portion of the first substrate to the desired thickness of the thinned substrate.

The method can also include forming a second patterned layer on the first substrate on a side of the first substrate opposite that of the first patterned bonding layer. The second patterned layer on the first substrate can include at least a first region and a second region. The first region is comprised of a conductive material and the second region is comprised of a non-conductive material. The method can also include forming a patterned bonding layer on a third substrate. The patterned bonding layer on the second substrate can include at least a first region and a second region. The first region is comprised of a conductive material and the second region is comprised of a adhesive material. The method can also include urging the first substrate and the third substrate together to bond at least a portion of the first region of the second patterned bonding layer of the first substrate to at least a portion of first region of the third substrate, and to bond at least a portion of the second region of the second patterned bonding layer of the first substrate and at least a portion of second region of the third substrate.

According to an aspect of the present invention, a device includes a first stratum of materials including a substrate and a second stratum of materials including a substrate. The device also includes a bonding layer situated between the substrate of the first stratum and the substrate of the second stratum. The bonding layer has a first region comprised of a metal and a second region comprised of an adhesive material. The first region of the bonding layer exhibits a substantially seamless boundary interface as viewed in cross-section by a scanning electron micrograph (SEM) view of the bonding interface. The second region of the bonding layer exhibits a substantially seamless boundary interface as viewed in cross-section by a scanning electron micrograph (SEM) view of the bonding interface.

Embodiments can include one or more of the following.

The adhesive material can be a partially cured polymer. The partially cured polymer can be benzocyclobutene (BCB). The adhesive material can be an organic adhesive material. The adhesive material can be an inorganic material. The metal can be copper. The metal can be a metal alloy. The first substrate can be a substrate selected from the group consisting of semiconductor substrates, glass substrates, ceramic substrates, silicon substrates, germanium substrates, and gallium arsenide substrates. The second substrate can be a substrate selected from the group consisting of semiconductor substrates, glass substrates, ceramic substrates, silicon substrates, germanium substrates, and gallium arsenide substrates.

The first stratum further can include a device layer that includes a plurality of electrical devices and an interconnect layer that includes a plurality of electrical interconnects. At least some of the electrical interconnects can be configured to form an electrical current path between a particular electrical device of the plurality of electrical devices and a corresponding metal region in the bonding layer. The second stratum further can include a device layer that includes a plurality of electrical devices and an interconnect layer that includes a plurality of electrical interconnects. At least some of the electrical interconnects can be configured to form an electrical current path between a particular electrical device of the plurality of electrical devices and a corresponding metal region in the bonding layer.

According to an aspect of the present invention, a device can include a first stratum including a substrate and a second stratum including a substrate. The device can also include a bonding layer formed by situating between the substrate of the first stratum and the substrate of the second stratum a non-conductive adhesive material. The device can be formed by attaching the substrates together to form the bonding layer.

Embodiments can include one or more of the following.

The bonding layer has a first region can be a metal and a second region can be composed of the non-conductive adhesive. The first region of the bonding layer exhibits a substantially seamless boundary interface as viewed in cross-section by a scanning electron micrograph (SEM) view of the bonding interface. The second region of the bonding layer exhibits a substantially seamless boundary interface as viewed in cross-section by a scanning electron micrograph (SEM) view of the bonding interface. The non-conductive adhesive material can be benzocyclobutene (BCB). The non-conductive adhesive material can be an organic adhesive material. The non-conductive adhesive material can be an inorganic material. The non-conductive adhesive can be a partially cured benzocyclobutene (BCB). The partially cured BCB can be BCB that has a crosslink percentage between 34% and less than 100%. The first region can be a metal which can be comprised of copper. The first substrate can be a substrate selected from the group consisting of semiconductor substrates, glass substrates, ceramic substrates, silicon substrates, germanium substrates, and gallium arsenide substrates. The second substrate can be a substrate selected from the group consisting of semiconductor substrates, glass substrates, ceramic substrates, silicon substrates, germanium substrates, and gallium arsenide substrates. The first stratum can include a device layer that includes a plurality of electrical devices and an interconnect layer that includes a plurality of electrical interconnects. At least some of the electrical interconnects can be configured to form an electrical current path between a particular electrical device of the plurality of electrical devices and a corresponding metal region in the bonding layer. The second stratum can include a device layer that includes a plurality of electrical devices and an interconnect layer that includes a plurality of electrical interconnects. At least some of the electrical interconnects can be configured to form an electrical current path between a particular electrical device of the plurality of electrical devices and a corresponding metal region in the bonding layer.

It is believed that wafer bonding of metal/adhesive redistribution layers for 3D integration with multi-layer stacks provides high interconnect bandwidth through high density inter-strata interconnectivity and a simplified, robust process for both inter-strata electrical interconnection and mechanical bonding.

It is believed that using a via-first approach that includes wafer bonding of damascene-patterned metal/adhesive redistribution layers provides various advantages. Bonding of damascene-patterned metal/adhesive redistribution layers provides both electrical and mechanical inter-wafer connections/bonds. This can combine the advantages of both BCB/BCB and Cu/Cu bonding. The bonding of damascene-patterned metal/adhesive redistribution layers can also provide advantages Kin thermal management. For example, the Cu/BCB “redistribution layer” can serve as a thermal conductor and/or spreader (with large percentage of Cu area or dense Cu grids or dense small Cu pads), as a thermal insulator (with large percentage of BCB area), and/or selected area for any kind. The bonding of damascene-patterned metal/adhesive redistribution layers can also provide high inter-wafer interconnectivity bandwidth while allowing large wafer-to-wafer alignment tolerance by eliminating deep inter-wafer vias. Using a “redistribution layer” as inter-wafer interconnect routing for wafers, on which the inter-wafer interconnect pads are not matched, can reduce the process flow and can be compatible with wafer-level packaging (WLP) technologies.

Wafer bonding of metal/adhesive redistribution layers for 3D integration with multi-layer stacks can be attractive for applications of monolithic wafer-level 3D integration (e.g., 3D interconnect, 3D ICs, wireless, and smart imagers, etc.) as well as wafer-level packaging, passives, microelectromechanical systems (MEMS), optical MEMS, bio-MEMS, and sensors.

It is believed that bonding substrates of multi-layer stacks using a partially cured polymer such as Benzocyclobutene (BCB) provides bonding layers having sufficient bond strength between the bonded multi-layer stacks.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a schematic representation of a bonded wafer stack.

FIG. 2 is a cross-sectional view of a bonding interface.

FIGS. 3A-C show cross-sectional views of bonding interfaces.

FIG. 4 is a cross-sectional view of a bonding interface.

FIGS. 5-13 are a series of cross-sectional views of a stratum.

FIG. 14 is a graph of a step height.

FIGS. 15-20 are a series of cross-sectional views of strata for a bonded wafer stack.

FIGS. 21 and 22 are schematic representations of a bonded wafer stack.

FIG. 23 is a schematic representation of a bonded wafer stack.

FIGS. 24 is a cross-sectional view of strata for a wafer stack.

### DETAILED DESCRIPTION

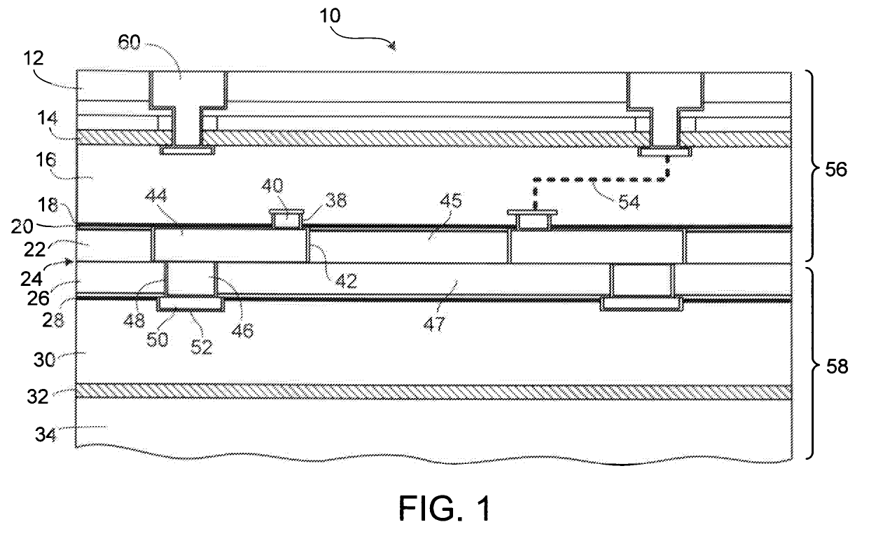

Referring to FIG. 1, a schematic representation of a bonded wafer stack 10 that includes two strata 56 and 58, bonded together at a bonding interface 24 is shown. In general, a stratum refers to a wafer layer which is stacked during a bonding process. For example, a stratum can be a wafer with multi-layer structures and devices. Stratum 58 includes a substrate 34, device layer 32, interconnect layer 30, barrier layer 28, and bonding layer 26. Substrate 34 can be provided by a variety of materials such as silicon, germanium, silicon-germanium, gallium arsenide, glass, silicon-carbide and so forth. Device layer 32 is supported by substrate 34 and includes various semiconductor devices such as transistors, resistors, and capacitors. Device layer 32 can be integral to substrate 34 or can be deposited onto substrate 34. The devices included in device layer 32 are electrically connected via single or multi-level on chip interconnects (not shown) that are disposed in the insulating layer 30. Conductive contacts 50, which can be part of the interconnect layer 30, form an electrical connection between the interconnects in layer 30 and the conductive regions 46 in the bonding layer 26.

Stratum 56 includes a thinned substrate 12 that is a result of a post-wafer-bonding backside thinning process over its original full-thickness substrate, a device layer 14, an interconnect layer 16, a barrier layer 18, and a bonding layer 22. The device layer 14, interconnect layer 16, barrier layer 18, and bonding layer 22 included in stratum 56 can be similar to the layers in stratum 58. The bonding layer 22 is bonded to bonding layer 26 at a bonding interface 24. Stratum 56 also includes electrical contacts 60. Contacts 60 are provided subsequent to bonding stratum 56 to stratum 58 and provide electrical contact between external devices (not shown) and the electrical devices included in device layers 32 and 14.

Bonding layer 22 of stratum 56 is bonded to bonding layer 26 of stratum 58 forming a mechanical connection between the strata 56 and 58, providing electrical connections between strata 56 and 58. The bonding layers 22 and 26 include conductive regions such as metal regions 46 and 44 and non-conductive adhesive portions such as regions 45 and 47 comprised of a non-conductive adhesive. In general the adhesive material can be a thermosetting polymer, thermoplastic polymer (i.e., polyimides), or dielectric adhesive. Examples of the metal include copper (Cu), gold (Au), and other metals or alloys. Examples of such non-conductive adhesives include Benzocyclobutene (BCB), Flare (a poly arylene ether polymer), other polymers or polyimides or dielectrics.

In the embodiments discussed below, copper and BCB are selected as the metal and adhesive in the bonding layers 22 and 26, with tantalum (Ta) as the liner metal for copper. However, other metal and adhesive materials can be used. In the embodiments described below, the adhesive regions 45 and 47 are here comprised of BCB (hereinafter BCB regions 45 and 47) and are partially cured prior to bonding. For example, the BCE regions 45 and 47 can be at least about 34% cured prior to bonding (e.g., at least about 40% cured, at least about 50% cured, at least about 60% cured). It is believed that partially curing the BCB layers prior to bonding provides various advantages such as improving the mechanical strength of the adhesive for patterning capability of Cu/BCB redistribution layer, while providing sufficient wafer bonding strength. The patterned Cu/BCB layers are bonded under controlled temperature and pressure, as described below.

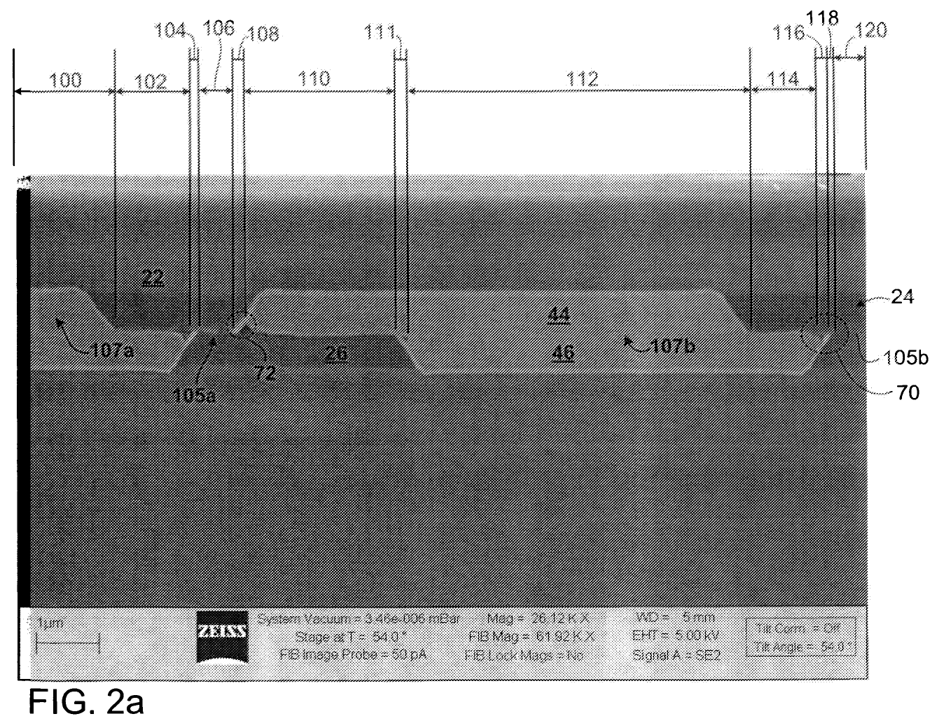

Referring to FIGS. 2 and 3A-3C and 4, cross-sectional scanning electron micrograph (SEM) views of bonding interface 24 are shown. The bonding interface 24 includes BCB-to-BCB interface regions (e.g., regions 106 and 120), BCB-to-tantalum interface regions (e.g., regions 104, 108, and 118), BCB-to-copper interface regions (e.g., regions 102, 110, and 114), and copper-to-copper interface regions (e.g., regions 100 and 112).

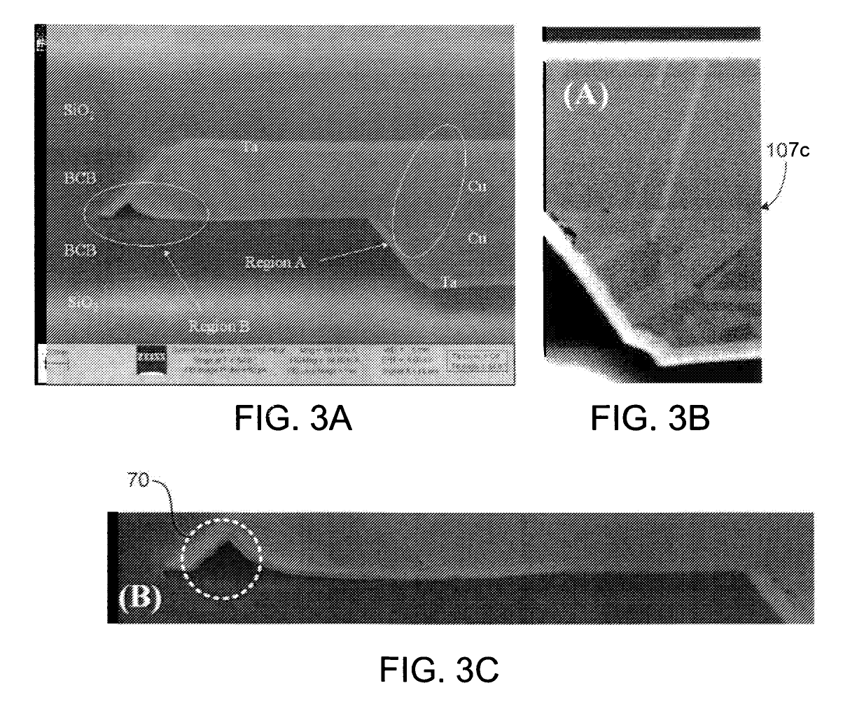

As -shown in FIG. 3A, both the BCB-to-BCB interfaces 105a and 105b and the copper-to-copper interfaces 107a and 107b are almost seamless, indicative of good bonding characteristics.

As shown in FIG. 3B, the copper-to-copper interface 107c includes some grain boundaries that cross the original copper-to-copper bond interface. The formation of grain boundaries that cross the bonding interface indicates that a bond has formed between the copper regions. The copper-to-copper bonding also allows the copper to migrate to fill potential voids in the copper-to-copper interface.

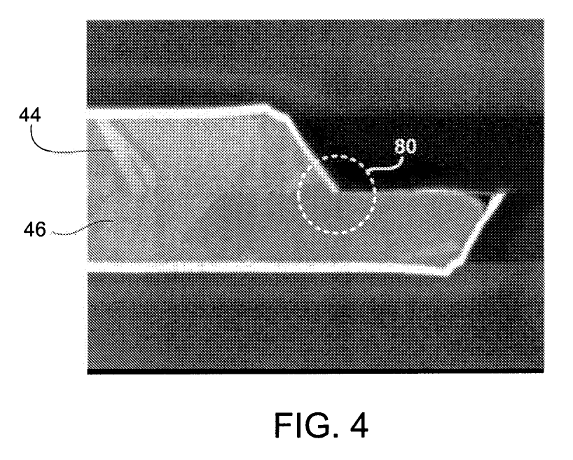

For example, as shown in FIG. 4, during bonding, it is believed that copper from layer 46 migrates to fill a void in copper layer 44 in region 80.

While both the copper-to-copper and BCB-to-BCB regions appear to be well bonded, as shown above, the copper-to-BCB regions do not appear to be bonded as shown in FIG. 3C, but instead are simply in mechanical contact due to the bonds in the other regions. The bonded interface 24 also includes a void (as indicated by circle 70) in portions of the BCB-to-copper/tantalum interface. It is believed that such voids are formed during cooling of the bonded wafer stack from the bonding temperature to room temperature, by non-planarity of the Cu patterning process (e.g., due to over-etching of edges of the copper regions during a chemical mechanical polishing (CMP) process), and/or by copper migration during the bonding at elevated temperature. For example, in region 80 in FIG. 4, such voids may be filled if the sizes of two bonding Cu pads are same and the two bonding pads are precisely aligned. Note that the BCB does not flow into the void as indicated by circle 70 in FIG. 3C. This fact implies that the copper-to-copper bond will not be contaminated by the partially-cured BCB, attributed to that the partially-cured BCB (e.g., −55% cured BCB) does not flow during the bonding process.

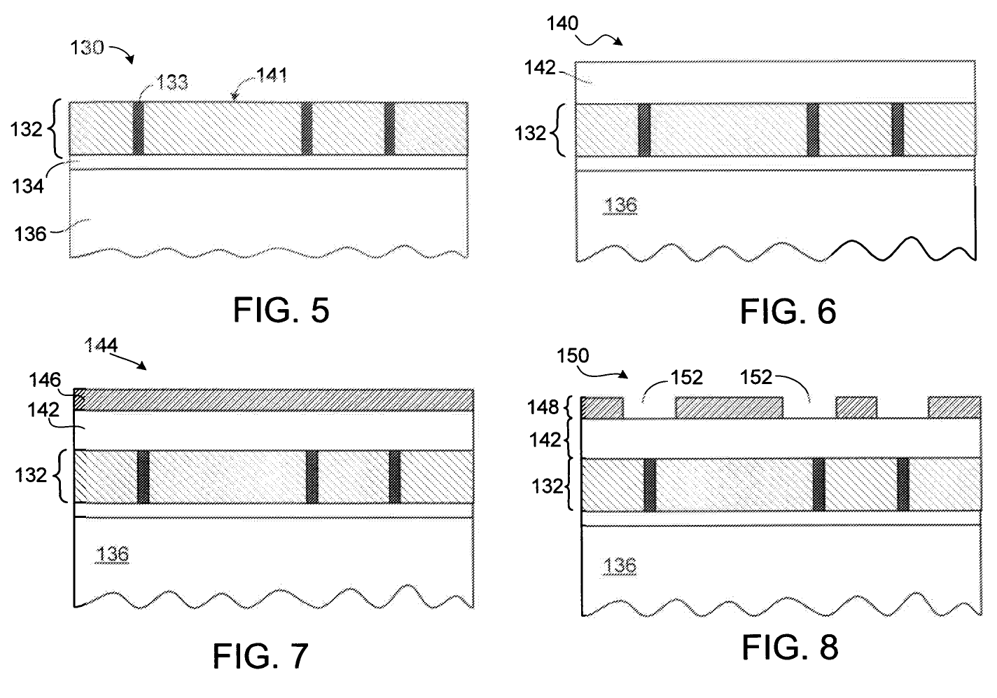

In general, the bonding layers 22 and 26 and the bonded multilayer stack 10 shown in FIG. 1 can be fabricated using various techniques and sequences. A typical fabrication process involves various deposition processes, lithography processing, etching, planarization, surface treatment, wafer-to-wafer alignment and bonding processes. In some embodiments, the bonded stack 10 is fabricated by the techniques shown in FIGS. 5-20 below.

Referring to FIG. 5 a wafer 130 comprised of a stratum including a substrate 136, a device layer 134, and an interconnect layer 132 is shown. The substrate 136 is provided as described above for substrate 34, and layers 134 and 132 are provided as generally described above with respect to layers 32 and 30, respectively. The metal line 133 represents a simple interconnect. The surface 141 may contain the barrier layer 28 as shown in FIG. 1.

Referring to FIG. 6, subsequent to formation of the interconnect layer 132, a layer of BCB 142 is deposited onto surface 141 of the interconnect layer 132. Layer 142 is deposited using any desired technique, such as, for example, spin coating, spread coating, vapor deposition, and so forth. In some embodiments, an adhesion promoter may be applied prior to the deposition of the BCB layer 142 to promote adhesion between the BCB layer 142 and the surface 141 of the interconnect layer 132. An example of adhesion promoter for BCB is the commercially available AP3000 that consists of silane-based molecules and a vinyl reactive functional group. The BCB layer 142 is partially cured such that cross-linking of the BCB material is at least 30% and preferably from about 45% to about 65% (e.g., about 45%, about 50%, about 55%, about 60%, about 65%). Layer 142 can be, for example, at least about 0.3 micron thick (e.g., at least about 0.3 micron thick, at least about 0.5 micron thick, at least about 1 micron thick, at least about 1.3 microns thick, at least about 1.5 microns thick, at least about 2 microns thick) and/or at most about three microns thick (e.g., at most about two microns thick). The thickness of the BCB layer 142 can be selected based on non-uniformity of the surface 141. The BCB layer 142 is cured using various processes. For example, the BCB can be heated to a temperature of about 210° C. for about 16 minutes or 250° C. for about one minute resulting in a cross-linking of approximately 55%. Other times and temperatures can be used to achieve greater or lesser cross-linking.

Referring to FIGS. 7 and 8, a lithography layer 146 (e.g., a photoresist layer) is deposited onto the partially cured BCB layer 142 (FIG. 7). The lithography layer 146 is patterned to form a patterned lithography layer 148 (FIG. 8). The thickness of layer 146 is selected as desired based on selectivity of subsequent etching processes. In general, layer 146 is, for example, at least about 0.5 microns thick (e.g., at least about 1 micron thick, at least about 1.5 microns thick, at least about 2 microns thick or increments in between).

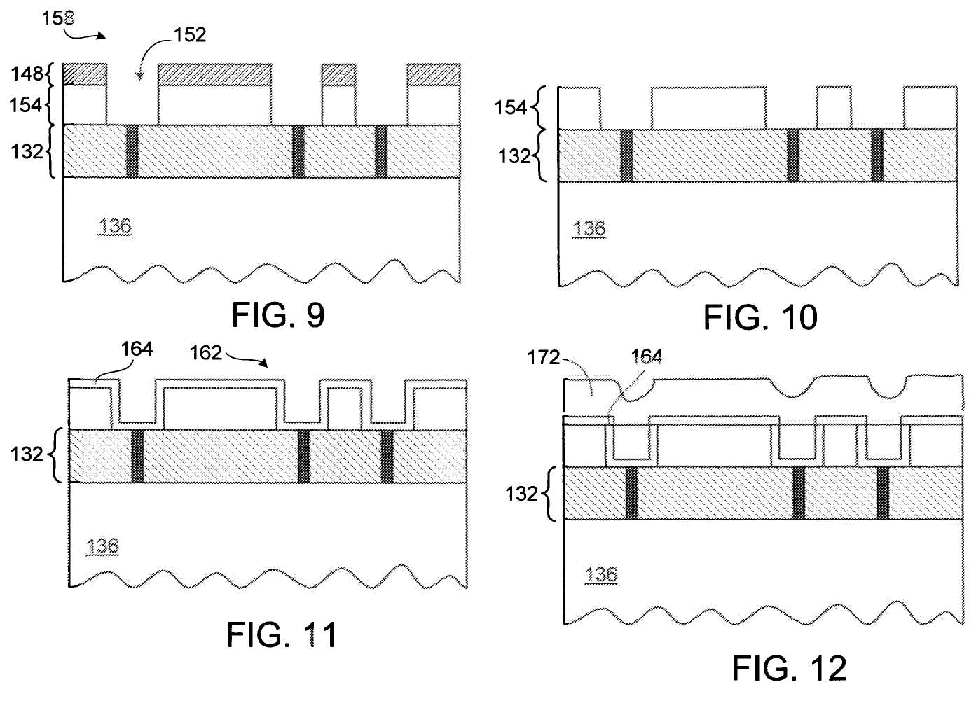

Referring to FIG. 9, the pattern in the photoresist layer 148 is transferred to the BCB layer 142 to form a patterned BCB layer 154. For example, the BCB layer 142 can be etched using an inductively coupled plasma (ICP) reactive ion etching (RIE) technique with C₄F₈ and O₂as the reactive species. The photoresist to BCB selectivity of this C₄F₈ etch is about 1:1, depending the mixture of C₄F₈ and O₂, and other etching parameters. The photoresist thickness can be selected such that the photoresist is entirely consumed during the etch process or the photoresist can be removed using standard techniques (as shown in FIG. 10).

Referring to FIG. 11, a barrier layer 164 (also called liner layer, e.g., a layer composed of Tantalum) is deposited onto the patterned BCB layer 154. Barrier layer 164 can prevent or limit diffusion or chemical reactions between materials in the stratum and/or to assist with adhesion between different layers (e.g., between the interconnects and the copper layers).

Referring to FIG. 12, a copper layer 172 is deposited (e.g., sputtered) onto the barrier layer 164. The copper layer 172 should be thick enough to completely fill the etched regions in the patterned BCB layer 154.

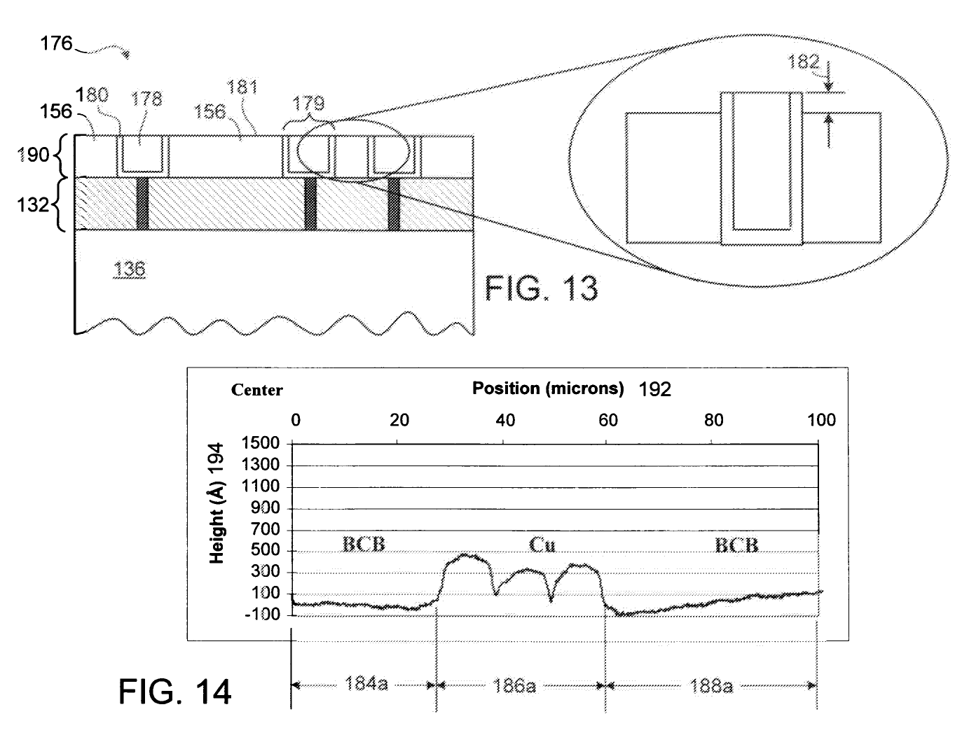

Referring to FIG. 13, layer 172 is polished and/or etched (e.g., using chemical mechanical polishing (CMP)) removing the copper from regions above the BCB and exposing the surface 181 of the patterned BCB layer 154. The portions barrier layer 164 and copper layer 172 in the indents between the regions of the barrier layer 164 remain, forming patterned conductive regions 179 that include a patterned barrier layer 180 and a patterned copper region 178. The patterned BCB regions 156 and conductive regions 179 together form a patterned bonding layer 190. The patterning process in FIGS. 10 to 13 is sometimes referred to as damascene patterning process in the literature.

Due to differences in removal rates among copper, tantalum and BCB, the CMP process may result in feature scale non-planarity across the surface of the wafer. For example, if the copper and tantalum have a lower removal rate than the BCB, the copper can be slightly raised (as indicated by arrow 182) with respect to the BCB after CMP.

Considering the difference of coefficient of thermal expansion (CTE) between copper and BCB, it is believed that a slight step height 182 can be desirable because it allows the copper surfaces to “touch down” first and deform during bonding with elevated temperature and bonding force, thus to make good electrical interconnection between the copper areas. On the other hand, higher CTE of BCB compared to that of copper allows the BCB surfaces to be bonded at BCB bonding temperature. When both copper bonding and BCB bonding are completed, and the bonded strata are cooled down to room temperature, a desired compressive stress from the BCB bond is resulted over the copper bonds due to CTE mismatch between copper and BCB.

FIG. 14 shows a graph of the step height 182 between the BCB and Cu regions of approximately 500 Å (Angstroms).

However, the CMP process can leave particles or other contaminants on the surface of the wafer that could possibly interfere with bonding. A post-CMP clean is performed to remove such contaminants from the surface prior to bonding. A simple post-CMP clean can include a post CMP brush cleaning using deionized water and polyvinyl alcohol (PVA) brushes.

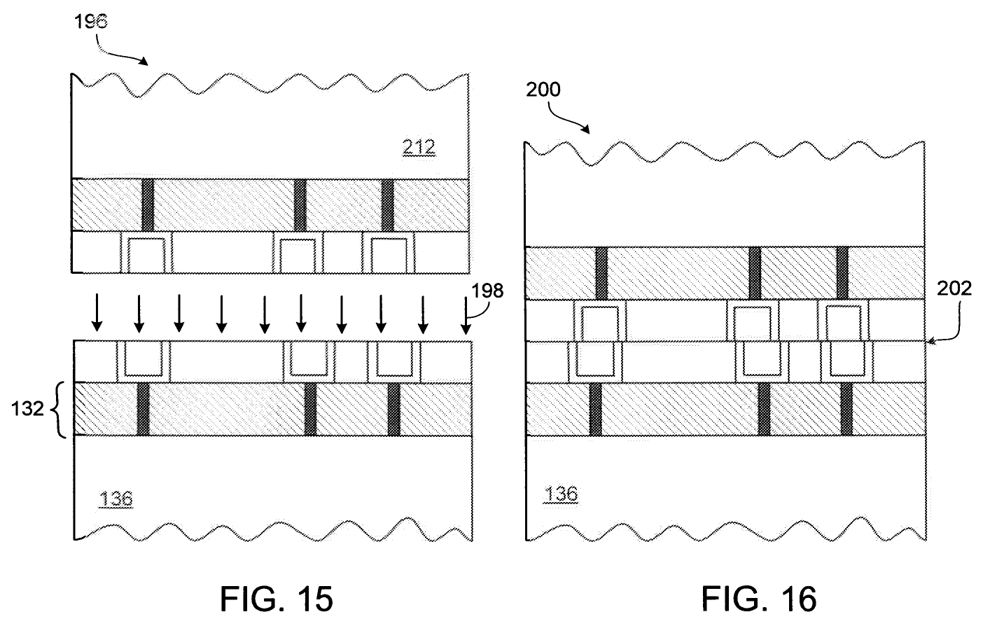

As shown in FIGS. 15 and 16, subsequent to forming the damascene-patterned bonding layer 190, the wafers are aligned (FIG. 15) and subsequently bonded (FIG. 16) in a vacuum chamber. The 200 mm wafers are bonded using a bond force from about 8,000 N (Newtons) to about 12,000 N and a temperature from about 200° C. to 400° C. An exemplary bonding process can include applying a mechanical down-force of about 10,000 N, a temperature ramp to 250° C., a soak for 60 minutes, followed by a further ramp to 350° C., soak for 60 minutes, and cooling to room temperature.

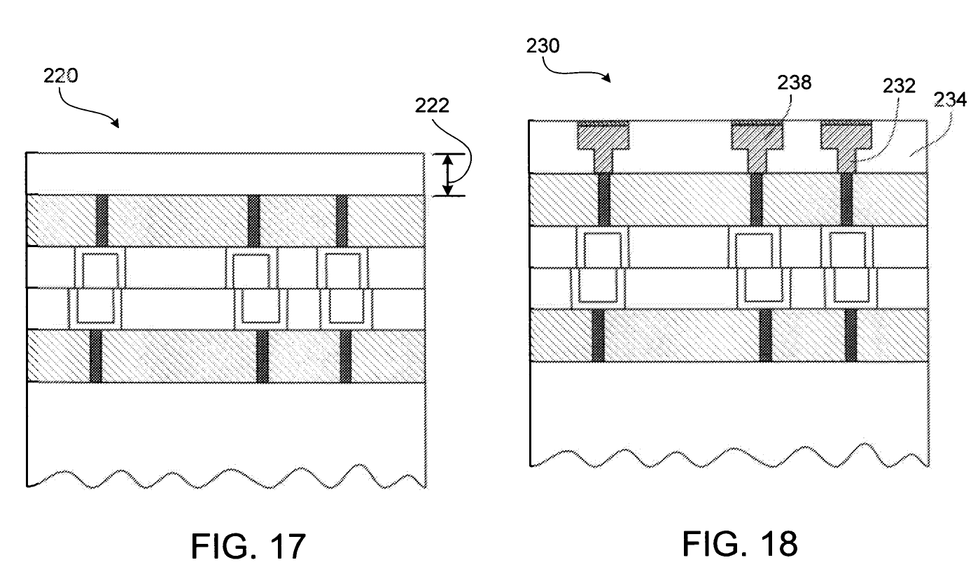

Subsequent to bonding, substrate 212 is at least partially removed to facilitate formation of a high density of contacts to the bonded wafer stack. For example, the substrate 212 has an initial thickness after bonding that is about equal to the initial thickness of the substrate. Substrate 212 can be thinned using a multi-step process resulting in a thickness 222 of about 50 microns or thinner as shown in FIG. 17. The substrate can be thinned through grinding and polishing, followed by a wet chemical etch. In some embodiments, substrate 212 is a silicon on insulator (SOI) substrate, e.g., a layer structure of thin active silicon (Si) on silicon dioxide (SiO₂) and on bulk silicon substrate. In this embodiment, an etch in tetramethyl ammonium hydroxide (TMAH), which has a high Si-to-SiO₂ selectivity (e.g., a selectivity of about 4000 to 1), can be used to remove the bulk silicon substrate, leaving the insulator (i.e., SiO₂) and the thin active silicon layer, subsequent to the grinding and polishing.

Subsequent to thinning substrate 212, apertures can be etched in the substrate and filled with a conductive material (e.g., copper) to form via contacts 232, with a process similar to the damascene-patterning process described above. In addition, an insulating layer can be deposited and patterned to form electrical contact pads 238.

The vias 232 and pads 238 can also be formed in one process, for example, as follows: apertures, which are used for via 232 formation, on substrate 212 are pre-opened when the device layer are formed, and filled with insulating material. An insulating layer is deposited after the wafer is thinned to the thin layer 222 and the pre-filled apertures are exposed. Then a dual-damascene patterning process is used to form the vias 232 and pads 238 in layer 234.

In some embodiments, it can be beneficial to form a wafer stack that includes more than two wafers (e.g., three wafers, four wafers, five wafers, etc.). The bonding process described above can be repeated to allow bonding of multiple wafers.

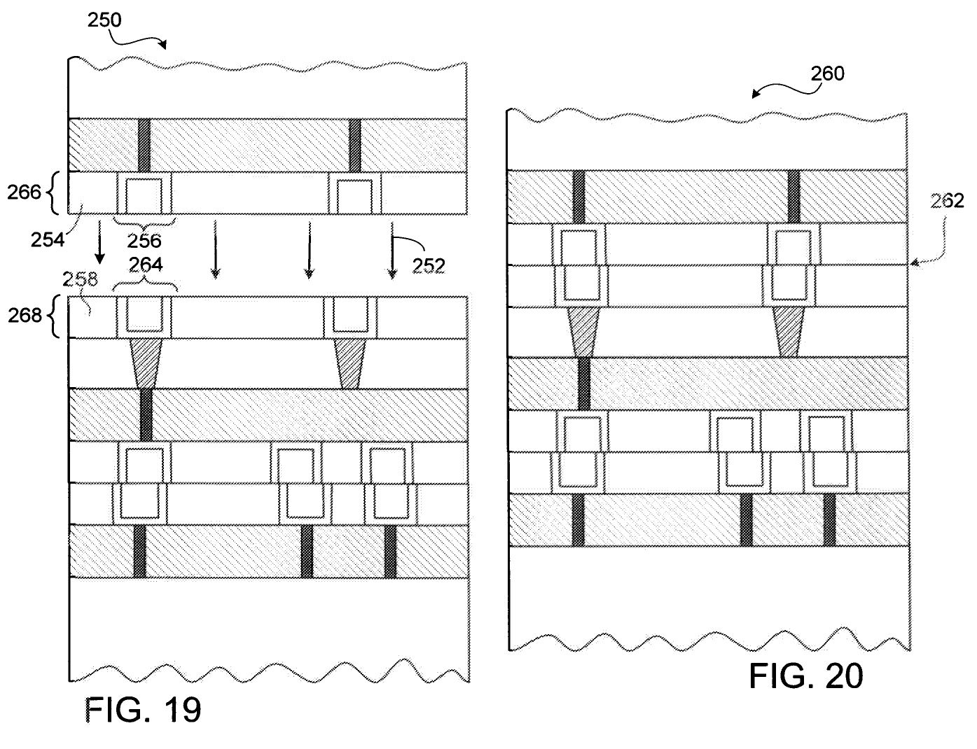

For example, rather than forming contact pads 238 on the surface of the wafer subsequent to bonding and thinning (e.g., as shown in FIG. 18) an additional bonding layer 268 can be deposited (e.g., as shown in FIG. 19). The bonding layer can include regions of partially cured BCB 258 and regions of conductive material 264 as described above.

As shown in FIG. 20, the wafer stack can then be bonded to another wafer having a bonding layer 266. While the initial bonding interface forms a front to front bond of the two interfaces closest to the device layer, the second bonding interface is a back to front bond bonding the backside (i.e., the side with the thinned substrate) of the previous wafer stack to the front side of the new wafer. This process can be repeated to form a stack of the desired number of strata.

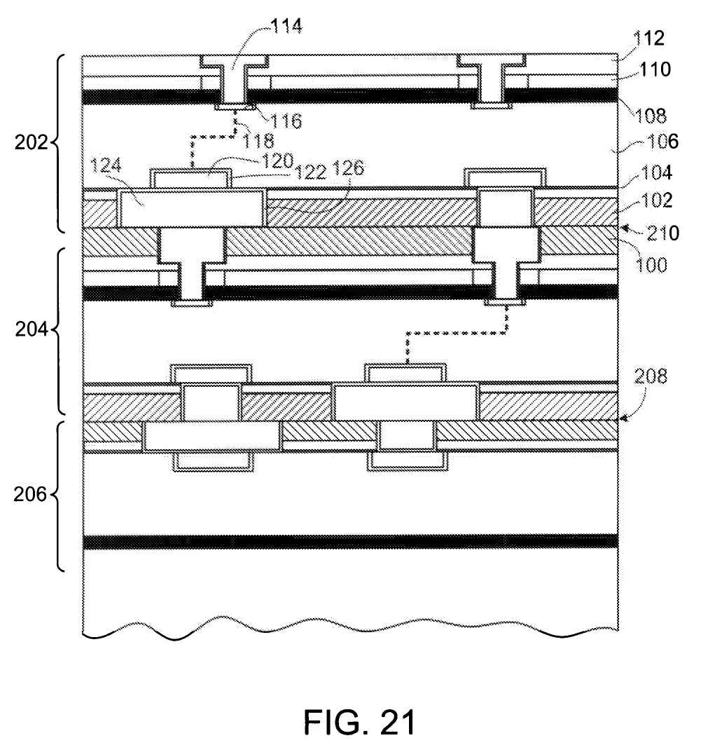

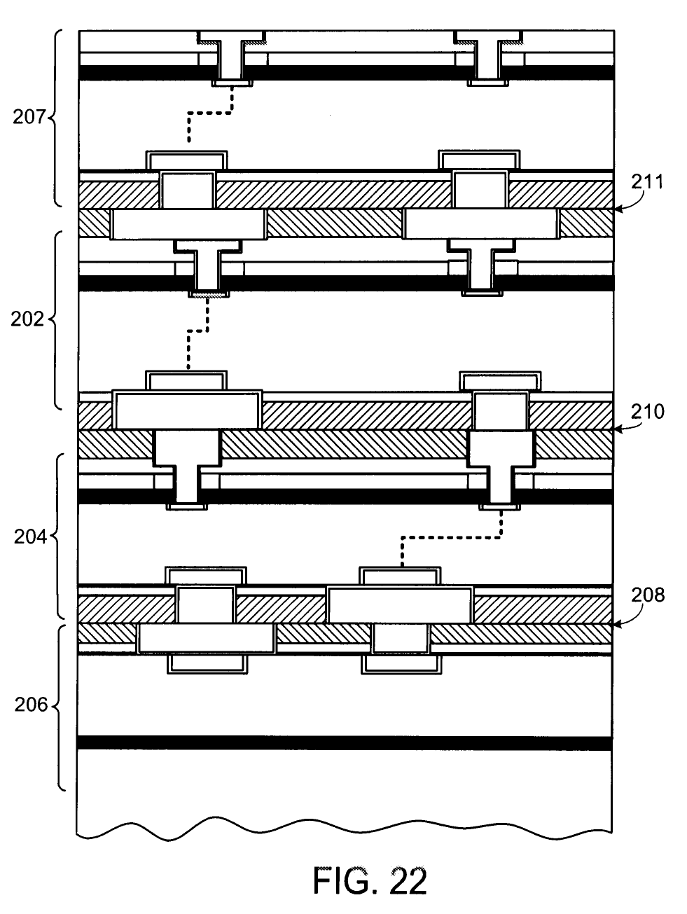

FIG. 21 shows a schematic bonded wafer stack 200 composed of three wafers 202, 204, and 206 bonded at bonding interfaces 208 and 210 is shown. FIG. 22 shows an exemplary bonded wafer stack 200 composed of four wafers 202, 204, 206, and 207 bonded at bonding interfaces 208, 210, and 211.

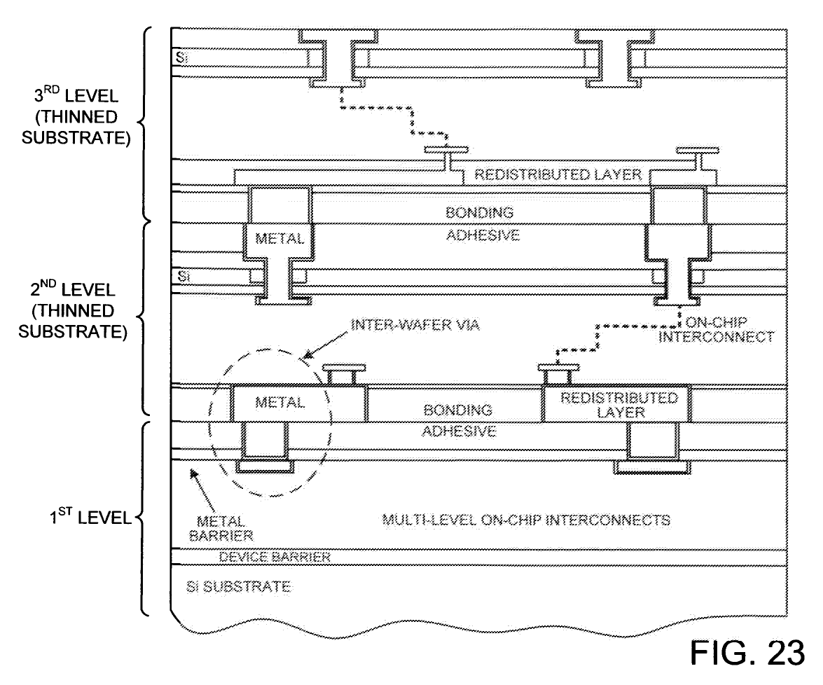

FIG. 23 illustrates a schematic of a via-first 3D integration approach, which employs wafer bonding of damascene-patterned metal/adhesive redistribution layers on two wafers. The wafer bonding of the patterned layers provides inter-wafer electrical interconnects (via-first) and adhesive bonding of two wafers in one unit processing step. A damascene patterned Cu/BCB redistribution layer is disposed over the uppermost interconnect layer of a second wafer, which is then flipped, aligned, and bonded to another patterned Cu/BCB layer on the first wafer.

The substrate of the face-down bonded second wafer is then thinned by mechanical grinding with optional chemical-mechanical polishing (CMP), followed by optional wet-chemical etching, wherein one of the options (CMP and wet etching) may be required.

The process can be extended to multiple wafer stacks by etching through the thinned second wafer of the bonded pair to create another damascene patterned layer, which mates with a third wafer.

A damascene patterned layer on top of the stack can be formed through the thinned third wafer substrate, similar to that on the backside of the thinned second wafer (top of the two-wafer stack). This patterned layer can serve as inter-wafer pads for further multiple wafer stacking, or as inputs/outputs (I/Os, including power/ground) for connecting the stack to outside world. In some embodiments, apertures within the thinned silicon layers on second and third wafer levels, where the through-wafer metal connections are formed, can be preformed during the device fabrication on the wafers, or after the backside substrate of the wafers are thinned.

There are several options for redistribution layer formation. In some embodiments, for the first two wafer stacking, one damascene patterned Cu/BCB redistribution layer can be disposed over the uppermost interconnect layer of the second wafer. The redistribution layer is formed to redistribute the connections on the second wafer to match the simple patterned Cu/BCB layer on the first wafer, e.g., simple Cu posts patterned within the BCB layer. In some embodiments, the patterned Cu/BCB layer on the first wafer can also be a Cu/BCB redistribution layer (not shown in FIG. 23). In some embodiments, if a redistribution of the interconnections is not required, the patterned Cu/BCB layer on the front side of the second wafer can be simple Cu posts patterned within the BCB layer (not shown in FIG. 23). These Cu posts can be similar to the simple patterned Cu/BCB layer on the first wafer. In some embodiments, the patterned Cu/BCB layer on the thinned second wafer substrate (e.g., the backside of the second wafer after substrate thinning) on top of the first two wafer stack can also be a Cu/BCB redistribution layer (not shown in FIG. 23). In some embodiments, an additional Cu/oxide (or Cu/BCB, or other metal/dielectric) redistribution layer (e.g., that over the uppermost metal layer of the third wafer as shown in FIG. 23) can be added prior to patterning process of any Cu/BCB bonding layer. The additional redistribution layer can simplify the patterning process of Cu/BCB bonding layer because only Cu bonding posts (vias) are needed. This approach with extra redistribution layer also offers a simple bonding scheme, i.e., with minimum misalignment one is always bonding Cu posts to Cu posts and BCB field to BCB field, avoiding undesirable contact (e.g., bonding) of long Cu lines with BCB field. Most importantly, this approach provides much more redistribution capability than that combining Cu bonding vias with the redistribution layer, although the approach without extra redistribution layer (e.g., the bonding layer serves also as a redistribution layer) can be a simpler approach.

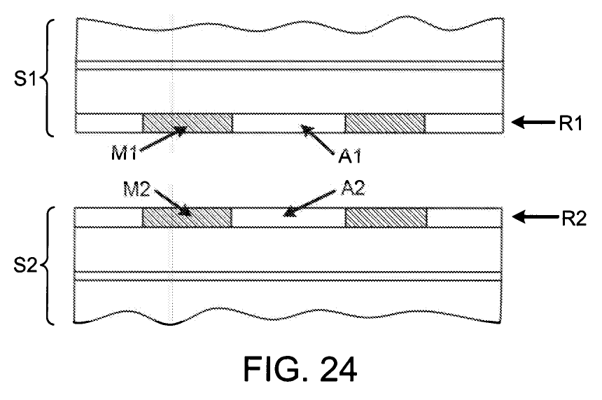

While particular embodiments have been described above, FIG. 24 shows a general description of two strata for bonding. The bonding employs wafer bonding of damascene-patterned metal/adhesive redistribution layers on two wafers. In general, stratum 1 (S1) & stratum 2 (S2), can be different materials, be processed differently, contain different functional devices, circuits, or components. Metal 1 (M1) & metal 2 (M2), are conductive materials to be bonded, to form inter-strata electrical interconnects. M1 and M2 can be different metals or alloys, or other highly conductive materials. M1 can be a different material from M2. In general, M1 & M2 are usually highly thermally conductive. In S1 and S2, adhesive 1 (A1) and adhesive 2 (A2) are generally non-conductive adhesive materials, e.g., BCB, or other polymers, SiO₂ or other inorganic dielectrics. A1 can be different from A2 in terms of material choices, e.g., A1 can be a partially-cured BCB while A2 can be SiO₂.

R1 & R2 are the bonding layers. One of or both of A1 and A2 can be a redistribution layer to redistribute the inter-strata interconnects. The redistribution layer can be formed within the R1 & R2, or can be formed as an extra layer formed prior to formation of the R1, or R2, or both. Surface areas and shapes of M1 & M2 can be the same or different. In some embodiments, it can be preferable for M1 and M2 to have the same area and/or shape. Surface areas and shapes of A1 & A2 can be the same or different. In some embodiments, it can be preferable for A1 and A2 to have the same area and/or shape. In some embodiments, an area ratio of M1/A1 and M2/A2 can be varied for thermal management options through the bonding interface. Design of R1 and R2 allows high inter-strata interconnect bandwidth and large strata-alignment tolerance.

While in some of the embodiments described above, the bonding layers 22 and 26 have been described as including copper regions 46, other conductive materials may be used to form the electrical contacts. For example, the conductive regions may be formed of various materials such as gold, aluminum, silver, platinum, copper, and other metals or metal alloys.

While in some of the embodiments described above certain semiconductor materials have been described, other semiconductor materials may also be used. In general, any semiconductor materials (e.g., III-V semiconductor materials, organic semiconductor materials, silicon) can be used that can be used in a semiconductor device.

Accordingly, other embodiments are within the scope of the following claims.

What is claimed is:

1. A method comprising:
forming a patterned bonding layer on a first substrate, the patterned bonding layer on the first substrate including a first region and a second region, the first region comprised of a conductive material and the second region comprised of a non-conductive adhesive material;
forming a patterned bonding layer on a second substrate, the patterned bonding layer on the second substrate including a first region and a second region, the first region comprised of a conductive material and the second region comprised of a non-conductive adhesive material;
urging the first substrate and the second substrate together to bond at least a portion of the first region of the patterned bonding layer of the first substrate and at least a portion of the first region of the patterned bonding layer of the second substrate, and to bond at least a portion of the second region of the patterned bonding layer of the first substrate and at least a portion of the second region of the patterned bonding layer of the second substrate.

2. The method of claim 1, wherein the non-conductive adhesive material comprises a patternable adhesive.

3. The method of claim 2, wherein the non-conductive adhesive material comprises benzocyclobutene (BCB).

4. The method of claim 1, wherein the conductive material comprises metal.

5. The method of claim 4, wherein the metal comprises copper.

6. The method of claim 1, further comprising chemical or plasma cleaning of at least one of the first substrate and the second substrate prior to bonding the first substrate to the second substrate.

7. The method of claim 1, wherein forming the patterned bonding layer on the first substrate comprises:
depositing an adhesive layer onto the first substrate;
partially curing the adhesive layer;
etching the adhesive layer to form a patterned adhesive layer; and
depositing the conductive material onto the patterned adhesive layer.

8. The method of claim 7, wherein forming a patterned bonding layer on a first substrate further comprises:
removing portions of the conductive material disposed above the adhesive material to form a nearly planar surface.

9. The method of claim 1, wherein non-conductive adhesive material comprises a partially cured polymer layer.

10. The method of claim 9, wherein the polymer layer has a crosslink percentage between 30% and 50%.

11. The method of claim 1, wherein forming the patterned bonding layer on the second substrate comprises:
depositing a adhesive layer onto the second substrate;
partially curing the adhesive layer if needed and applicable;
etching the adhesive layer to form a patterned adhesive layer; and
depositing the conductive material onto the patterned adhesive layer.

12. The method of claim 11, wherein the adhesive layer comprises a partially cured polymer layer.

13. The method of claim 11, wherein forming a patterned bonding layer on a second substrate further comprises:
removing portions of the conductive material situated above the adhesive material to form a nearly planar surface.

14. The method of claim 11, wherein partially curing the polymer layer comprises curing the polymer layer such that the polymer layer has a crosslink percentage between 30% and 50%.

15. The method of claim 1, wherein attaching the first substrate to the second substrate comprises:
applying a uniform pressure to the substrates, the pressure being at least about 40 PSI; and
heating the first substrate and the second substrate to a temperature from about 250 degrees to about 400 degrees.

16. The method of claim 1, further comprising removing a portion of the first substrate subsequent to bonding the first substrate to the second substrate.

17. The method of claim 16, wherein removing a portion of the first substrate comprises:
mechanically grinding the first substrate to remove a first portion of the first substrate,
performing a chemical mechanical polishing (CMP) process to remove damage caused by grinding process;
chemically etching the first substrate to remove a second portion of the first substrate to the desired thickness of the thinned substrate.

18. The method of claim 16, further comprising:
forming a second patterned layer on the first substrate on a side of the first substrate opposite that of the first patterned bonding layer, the second patterned layer on the first substrate including at least a first region and a second region, the first region comprised of a conductive material and the second region comprised of a non-conductive material;
forming a patterned bonding layer on a third substrate, the patterned bonding layer on the second substrate including at least a first region and a second region; the first region comprised of a conductive material and the second region comprised of a adhesive material; and
urging the first substrate and the third substrate together to bond at least a portion of the first region of the second patterned bonding layer of the first substrate to at least a portion of first region of the third substrate, and to bond at least a portion of the second region of the second patterned bonding layer of the first substrate and at least a portion of second region of the third substrate.
repeating the same processes, multi-level strata can be formed.

19. A device comprising:
a first stratum of materials comprising:
a substrate; and
a second stratum of materials comprising:
a substrate; and
a bonding layer situated between the substrate of the first stratum and the substrate of the second stratum, with the bonding layer having a first region comprised of a metal and a second region comprised of an adhesive material, with
the first region of the bonding layer exhibiting a substantially seamless boundary interface as viewed in cross-section by a scanning electron micrograph (SEM) view of the bonding interface; and
the second region of the bonding layer exhibiting a substantially seamless boundary interface as viewed in cross-section by a scanning electron micrograph (SEM) view of the bonding interface.

20. The device of claim 19, wherein the adhesive material comprises a partially cured polymer.

21. The device of claim 20 wherein the partially cured polymer comprises benzocyclobutene (BCB).

22. The device of claim 19, wherein the adhesive material comprises an organic adhesive material.

23. The device of claim 19, wherein the adhesive material comprises an inorganic material.

24. The device of claim 19, wherein the metal comprises copper.

25. The device of claim 19, wherein the metal comprises a metal alloy.

26. The device of claim 19, wherein the first substrate comprises a substrate selected from the group consisting of semiconductor substrates, glass substrates, ceramic substrates, silicon substrates, germanium substrates, and gallium arsenide substrates; and the second substrate comprises a substrate selected from the group consisting of semiconductor substrates, glass substrates, ceramic substrates, silicon substrates, germanium substrates, and gallium arsenide substrates.

27. The device of claim 19, wherein the first stratum further comprises:
a device layer that includes a plurality of electrical devices; and
an interconnect layer that includes a plurality of electrical interconnects, wherein at least some of the electrical interconnects are configured to form an electrical current path between a particular electrical device of the plurality of electrical devices and a corresponding metal region in the bonding layer.

28. The device of claim 19, wherein the second stratum further comprises:
a device layer that includes a plurality of electrical devices; and
an interconnect layer that includes a plurality of electrical interconnects, wherein at least some of the electrical interconnects are configured to form an electrical current path between a particular electrical device of the plurality of electrical devices and a corresponding metal region in the bonding layer.

29. A device comprising:
a first stratum comprising:
a substrate; and
a second stratum comprising:
a substrate; and
a bonding layer formed by situating between the substrate of the first stratum and the substrate of the second stratum a non-conductive adhesive material; and formed by:
attaching the substrates together to form the bonding layer.

30. The device of claim 28 wherein the bonding layer has a first region comprised of a metal and a second region comprised of the non-conductive adhesive,
with the first region of the bonding layer exhibiting a substantially seamless boundary interface as viewed in cross-section by a scanning electron micrograph (SEM) view of the bonding interface; and
the second region of the bonding layer exhibiting a substantially seamless boundary interface as viewed in cross-section by a scanning electron micrograph (SEM) view of the bonding interface.

31. The device of claim 29, wherein the non-conductive adhesive material comprises benzocyclobutene (BCB).

32. The device of claim 29, wherein the non-conductive adhesive material comprises an organic adhesive material

33. The device of claim 29, wherein the non-conductive adhesive material comprises an inorganic material.

34. The device of claim 29, wherein the non-conductive adhesive can be a partially cured benzocyclobutene (BCB).

35. The device of claim 33, wherein the partially cured BCB comprises BCB that has a crosslink percentage between 34% and less than 100%.

36. The device of claim 28, wherein the first region is a metal which can be comprised of copper.

37. The device of claim 28, wherein the first substrate comprises a substrate selected from the group consisting of semiconductor substrates, glass substrates, ceramic substrates, silicon substrates, germanium substrates, and gallium arsenide substrates; and the second substrate comprises a substrate selected from the group consisting of semiconductor substrates, glass substrates, ceramic substrates, silicon substrates, germanium substrates, and gallium arsenide substrates.

38. The device of claim 28, wherein the first stratum further comprises:
a device layer that includes a plurality of electrical devices; and
an interconnect layer that includes a plurality of electrical interconnects, wherein at least some of the electrical interconnects are configured to form an electrical current path between a particular electrical device of the plurality of electrical devices and a corresponding metal region in the bonding layer.

39. The device of claim 28, wherein the second stratum further comprises:
a device layer that includes a plurality of electrical devices; and
an interconnect layer that includes a plurality of electrical interconnects, wherein at least some of the electrical interconnects are configured to form an electrical current path between a particular electrical device of the plurality of electrical devices and a corresponding metal region in the bonding layer.
